(19) United States
(12) Patent Application Publication
(10) Pub. No.: US 2024/0355869 A1
(43) Pub. Date: Oct. 24, 2024

(54) COMPOSITE PASSIVE COMPONENT AND PREPARATION METHOD THEREFOR

(71) Applicant: Dynax Semiconductor, Inc., Suzhou (CN)

(72) Inventors: Chenggong YIN, Suzhou (CN); Ruopu ZHU, Suzhou (CN)

(73) Assignee: Dynax Semiconductor, Inc., Suzhou (CN)

(21) Appl. No.: 18/759,341

(22) Filed: Jun. 28, 2024

Related U.S. Application Data
(63) Continuation of application No. PCT/CN2022/143754, filed on Dec. 30, 2022.

(30) Foreign Application Priority Data
Dec. 31, 2021 (CN) 202111668110.1
Dec. 31, 2021 (CN) 202111673821.8

(51) Int. Cl. H01G 4/02

(52) U.S. Cl. CPC H01L 28/40

(57) ABSTRACT

A composite passive component includes: a substrate, an epitaxial structure and a passive component body. The epitaxial structure is set on the substrate, and a two-dimensional electron gas with a specific pattern is formed in the epitaxial structure. The passive component body is in ohmic contact with the two-dimensional electron gas.

### CROSS-REFERENCE TO RELATED APPLICATIONS

The present disclosure is a continuation of International Application No. PCT/CN2022/143754, filed on Dec. 30, 2022, which claims priority to Chinese Patent Application No. 202111668110.1, filed on Dec. 31, 2021, and Chinese Patent Application No. 202111673821.8, filed on Dec. 31, 2021. All of the aforementioned patent applications are hereby incorporated by reference in their entireties.

### TECHNICAL FIELD

Embodiments of the present disclosure relate to the field of capacitor, in particular, to a composite passive component and a preparation method for a composite passive component.

### BACKGROUND

On-chip composite passive component is one of the main components of modern RF/MM (Radio Frequency/Microwave Millimeter) circuits and has important applications in modern electronic technology.

However, with the development trend of miniaturization of electronic devices, requirements for integration level of the passive component are getting higher and higher, the integration level of existing passive components is low, which limits the application of passive component devices.

### SUMMARY

In a first aspect, embodiments of the present disclosure provide a composite passive component, where the composite passive component includes: a substrate; an epitaxial structure, set on the substrate, a two-dimensional electron gas with a specific pattern being formed in the epitaxial structure; and a passive component body, set on a side, away from the substrate, of the epitaxial structure, and being in ohmic contact with the two-dimensional electron gas.

In an embodiment, an isolation part is formed in the epitaxial structure, and the isolation part defines an area corresponding to the two-dimensional electron gas.

In an embodiment, the specific pattern of the two-dimensional electron gas is adaptively set with the passive component body.

In an embodiment, the composite passive component is a composite capacitor, the passive component body includes: a metal capacitor structure, set on the side, away from the substrate, of the epitaxial structure, the metal capacitor structure includes a first metal plate and a second metal plate, the second metal plate is located on a side, away from the substrate, of the first metal plate, and the first metal plate is insulated from the two-dimensional electron gas; and along a thickness direction of the composite passive component, a total projection, on the substrate, of the first metal plate and the second metal plate at least partially overlaps with a projection, on the substrate, of the two-dimensional electron gas.

In an embodiment, the two-dimensional electron gas is configured to be equipotential with the second metal plate; and along the thickness direction of the composite passive component, a projection, on the substrate, of the first metal plate at least partially overlaps with the projection, on the substrate, of the two-dimensional electron gas.

In an embodiment, the composite passive component further includes a connecting structure; where the connecting structure is in ohmic contact with the two-dimensional electron gas, and is electrically connected with the second metal plate.

In an embodiment, the composite passive component further includes: a first interlayer dielectric layer, covering the epitaxial structure; where the metal capacitor structure is set on a side, away from the substrate, of the first interlayer dielectric layer, the metal capacitor structure includes the first metal plate, the second metal plate and a second interlayer dielectric layer.

In an embodiment, a material of the epitaxial structure is a semiconductor material based on a III-V group compound.

In an embodiment, along the thickness direction of the composite passive component, the projection, on the substrate, of the two-dimensional electron gas covers the projection, on the substrate, of the first metal plate and a projection, on the substrate, of the second metal plate.

In an embodiment, the two-dimensional electron gas is insulated from the second metal plate.

In an embodiment, the two-dimensional electron gas is in a first planar spiral shape, the composite passive component is a composite inductor, and the passive component body includes: a first connecting metal layer, being in ohmic contact with a first end of the two-dimensional electron gas; an inductive metal wire, set on the side, away from the substrate, of the epitaxial structure, and the inductive metal wire being in a second planar spiral shape; a first connecting metal, where a first end of the first connecting metal is electrically connected with the first connecting metal layer, and a second end of the first connecting metal is electrically connected with a first end of the inductive metal wire; where the first end of the inductive metal wire is one end, corresponding to a center point of the second planar spiral shape, of the inductive metal wire; the first end of the two-dimensional electron gas is one end, corresponding to a center point of the first planar spiral shape, of the two-dimensional electron gas.

In an embodiment, a spiral direction of the first planar spiral shape is opposite to a spiral direction of the second planar spiral shape.

In an embodiment, a width of the two-dimensional electron gas is greater than a width of the inductive metal wire.

In an embodiment, the number of turns of the two-dimensional electron gas is greater than the number of turns of the inductive metal wire.

In an embodiment, the composite passive component further includes a first interlayer dielectric layer, a first electrode metal, a second electrode metal, a second connecting metal layer and a second connecting metal; the first interlayer dielectric layer is set on the side, away from the substrate, of the epitaxial structure; the inductive metal wire is set on a side, away from the substrate, of the first interlayer dielectric layer; the first electrode metal, the second electrode metal and the inductive metal wire are set on a same layer, and the first electrode metal is electrically connected with a second end of the inductive metal wire; the second connecting metal layer and the first connecting metal layer are set on a same layer, and the second connecting metal layer is in ohmic contact with a second end of the two-dimensional electron gas; and the second connecting metal penetrates through the first interlayer dielectric layer, a first end of the second connecting metal is electrically connected with the second connecting metal layer, and a second end of the second connecting metal is electrically connected with the second electrode metal.

In an embodiment, the composite passive component further includes a second interlayer dielectric layer, a first ohmic metallized through hole and a second ohmic metallized through hole; the second interlayer dielectric layer is set between the first interlayer dielectric layer and the epitaxial structure; the first ohmic metallized through hole penetrates through the second interlayer dielectric layer, the second ohmic metallized through hole penetrates through the second interlayer dielectric layer; and the first connecting metal layer is in ohmic contact with the first end of the two-dimensional electron gas through the first ohmic metallized through hole, the second connecting metal layer is in ohmic contact with the second end of the two-dimensional electron gas through the second ohmic metallized through hole.

In an embodiment, the composite passive component further includes a protective layer, covering the inductive metal wire.

In a second aspect, embodiments of the present disclosure further provide a preparation method for a composite passive component, including: providing a substrate; forming an epitaxial structure layer on the substrate by epitaxy; performing ion implantation on the epitaxial structure layer to form an isolation part, to define an area corresponding to a two-dimensional electron gas; setting a passive component body on a side, away from the substrate, of the epitaxial structure, and making the passive component body be in ohmic contact with the two-dimensional electron gas.

In an embodiment, the preparation method includes: forming an epitaxial structure on a substrate by epitaxy, a two-dimensional electron gas being formed in the epitaxial structure; forming a metal capacitor structure on the side, away from the substrate, of the epitaxial structure, the metal capacitor structure includes a first metal plate and a second metal plate, the second metal plate is located on a side, away from the substrate, of the first metal plate, and the first metal plate is insulated from the two-dimensional electron gas; and along a thickness direction of the composite passive component, a total projection, on the substrate, of the first metal plate and the second metal plate at least partially overlaps with a projection, on the substrate, of the two-dimensional electron gas.

In an embodiment, the forming a metal capacitor structure on the side, away from the substrate, of the epitaxial structure includes: forming the first metal plate, so that along the thickness direction of the composite passive component, a projection, on the substrate, of the first metal plate at least partially overlaps with a projection, on the substrate, of the two-dimensional electron gas; when forming the metal capacitor structure on the side, away from the substrate, of the epitaxial structure, the preparation method further includes: forming a connecting structure, where the connecting structure is in ohmic contact with the two-dimensional electron gas and is electrically connected with the second metal plate.

In an embodiment, the preparation method includes: forming an epitaxial structure on a substrate, the epitaxial structure including a two-dimensional electron gas in a first planar spiral shape; forming a first connecting metal layer on the side, away from the substrate, of the epitaxial structure, the first connecting metal layer being in ohmic contact with a first end of the two-dimensional electron gas; forming a first connecting metal and an inductive metal wire on the side, away from the substrate, of the epitaxial structure, where the inductive metal wire is in a second planar spiral shape, a first end of the first connecting metal is electrically connected with the first connecting metal layer, and a second end of the first connecting metal is electrically connected with a first end of the inductive metal wire; where the first end of the inductive metal wire is one end, corresponding to a center point of the second planar spiral shape, of the inductive metal wire;

the first end of the two-dimensional electron gas is one end, corresponding to a center point of the first planar spiral shape, of the two-dimensional electron gas.

In an embodiment, the forming an epitaxial structure on a substrate, the epitaxial structure including a two-dimensional electron gas in a planar spiral shape includes: forming an epitaxial structure layer on the substrate by epitaxy; and performing ion implantation on the epitaxial structure layer to form an isolation part, to define an area corresponding to the two-dimensional electron gas.

In an embodiment, before forming a first connecting metal and an inductive metal wire on the side, away from the substrate, of the epitaxial structure, the preparation method further includes: forming a first interlayer dielectric layer on the side, away from the substrate, of the epitaxial structure, a first through hole being formed in the first interlayer dielectric layer, and the first through hole exposing the first connecting metal layer; where the forming a first connecting metal on the side, away from the substrate, of the epitaxial structure includes: metallizing the first through hole to form the first connecting metal.

In an embodiment, before the forming a first connecting metal layer on the side, away from the substrate, of the epitaxial structure, the preparation method further includes: forming a second interlayer dielectric layer on the side, away from the substrate, of the epitaxial structure, where a first ohmic through hole and a second ohmic through hole are formed in the second interlayer dielectric layer, the first ohmic through hole exposes a first end of the two-dimensional electron gas, and the second ohmic through hole exposes a second end of the two-dimensional electron gas; where when forming the first connecting metal layer on the side, away from the substrate, of the epitaxial structure, the preparation method further includes: metallizing the first ohmic through hole to form a first ohmic metallized through hole, forming a second connecting metal layer on the side, away from the substrate, of the epitaxial structure, and metallizing the second ohmic through hole to form a second ohmic metallized through hole; where the first connecting metal layer is in ohmic contact with the first end of the two-dimensional electron gas through the first ohmic metallized through hole, the second connecting metal layer is in ohmic contact with the second end of the two-dimensional electron gas through the second ohmic metallized through hole; where when forming a first interlayer dielectric layer on the side, away from the substrate, of the epitaxial structure, the preparation method further includes: forming the first interlayer dielectric layer with a second through hole, and the second through hole exposing the second connecting metal layer; where when metallizing the first through hole to form the first connecting metal, and forming the inductive metal wire on the side, away from the substrate, of the first interlayer dielectric layer, the preparation method further includes: forming a first electrode metal on the side, away from the substrate, of the first interlayer dielectric layer, metallizing the second through hole to form a second connecting metal, and forming a second electrode metal on the side, away from the substrate, of the first interlayer dielectric layer; where the first electrode metal is electrically connected with a second end of the inductive metal wire; a first end of the second connecting metal is electrically connected with the second connecting metal layer, and a second end of the second connecting metal is electrically connected with the second electrode metal.

In the technical solution of embodiments, the passive component body may be a capacitor structure or an inductor structure.

In the technical solution of an embodiment, an adopted composite capacitor includes: a substrate; an epitaxial structure, set on the substrate, a two-dimensional electron gas being formed in the epitaxial structure; a metal capacitor structure, set on a side, away from the substrate, of the epitaxial structure, where the metal capacitor structure includes a first metal plate and a second metal plate, the second metal plate is located on a side, away from the substrate, of the first metal plate, and the first metal plate is insulated from the two-dimensional electron gas; and along a thickness direction of the composite capacitor, a total projection, on the substrate, of the first metal plate and the second metal plate at least partially overlaps with a projection, on the substrate, of the two-dimensional electron gas. The two-dimensional electron gas can be equivalent to one electrode plate of the capacitor, which can improve the number of capacitors and increase the integration level of the capacitor without increasing an occupied wafer area.

In the technical solution of an embodiment, an adopted composite inductor includes a substrate; an epitaxial structure, set on the substrate, a two-dimensional electron gas being formed in the epitaxial structure, and the two-dimensional electron gas being in a first planar spiral shape; a first connecting metal layer, being in ohmic contact with a first end of the two-dimensional electron gas; an inductive metal wire, set on a side, away from the substrate, of the epitaxial structure, and the inductive metal wire being in a second planar spiral shape; a first connecting metal, where a first end of the first connecting metal is electrically connected with the first connecting metal layer, and a second end of the first connecting metal is electrically connected with a first end of the inductive metal wire; where the first end of the inductive metal wire is one end, corresponding to a center point of the second planar spiral shape, of the inductive metal wire; and the first end of the two-dimensional electron gas is one end, corresponding to a center point of the first planar spiral shape, of the two-dimensional electron gas. When the size of a wafer occupied by the composite inductor is unchanged, a first inductor and a second inductor of the composite inductor are respectively set on different layers, thereby increasing the integration level of the inductor, and increasing the inductance of the composite inductor in series, that is, increasing the length of the current path on a unit wafer area, thereby increasing the inductance density of the composite inductor.

### BRIEF DESCRIPTION OF THE DRAWINGS

FIG. 1 is a structural schematic diagram of a composite capacitor according to an embodiment of the present disclosure.

FIG. 2 is a structural schematic diagram of a composite capacitor according to another embodiment of the present disclosure.

FIG. 3 is a structural schematic diagram of a composite capacitor according to another embodiment of the present disclosure.

FIG. 4 is a structural schematic diagram of a composite capacitor according to another embodiment of the present disclosure;

FIG. 5 is a flowchart of a preparation method for a composite capacitor according to an embodiment of the present disclosure.

FIG. 6 to FIG. 15 are structural schematic diagrams of products corresponding to main processes of a preparation method for a composite capacitor according to an embodiment of the present disclosure.

FIG. 16 is a top view of a composite inductor according to an embodiment of the present disclosure.

FIG. 17 is a cross-sectional view along the line A1A2 in FIG. 16.

FIG. 18 is another cross-sectional view along the line A1A2 in FIG. 16.

FIG. 19 is another cross-sectional view along the line A1A2 in FIG. 16.

FIG. 20 is a flowchart of a preparation method for a composite inductor according to an embodiment of the present disclosure.

FIG. 21 to FIG. 29 are structural schematic diagrams of products corresponding to main processes of a preparation method for a composite inductor according to an embodiment of the present disclosure.

### DETAILED DESCRIPTION OF THE EMBODIMENTS

The present disclosure will be further described in detail below with reference to the drawings and embodiments. It can be understood that, the specific embodiments described herein are merely used for explaining the present disclosure, rather than limiting the present disclosure.

In addition, it should be noted that, in order to facilitate the description, only part of the structures but not all of the structures related to the present disclosure are shown in the drawings.

An embodiment of the present disclosure provides a composite passive component, including: a substrate; and an epitaxial structure, set on the substrate, where a two-dimensional electron gas with a specific pattern is formed in the epitaxial structure; and a passive component body, set on a side, away from the substrate, of the epitaxial structure and being in ohmic contact with the two-dimensional electron gas with the specific pattern. Through an interaction between the two-dimensional electron gas in the epitaxial structure and the passive component body, the integration level and performance of the composite passive component are improved. The passive component may be a capacitor structure or an inductor structure.

Specifically, the substrate 11 may be, for example, one or a combination of gallium nitride, aluminum gallium nitride, indium gallium nitride, aluminum indium gallium nitride, indium phosphide, gallium arsenide, silicon carbide, diamond, sapphire, germanium, silicon, or any other material capable of growing group III nitride. The epitaxial structure 12 may be formed by growing on the substrate 11, the growing method, for example, may be any one of metal organic chemical vapor deposition (MOCVD), molecular beam epitaxy (MBE), and hydride vapor phase epitaxy (HVPE). The epitaxial structure 12 may include multiple layers, a material of each layer may be a semiconductor material based on a group III-V compound, and the epitaxial structure 12 may be, for example, a heterojunction, which is not specifically limited in this embodiment. After the epitaxial structure 12 is grown and formed, a layer of high concentration free charge will be formed inside the epitaxial structure 12, that is, a two-dimensional electron gas (2DEG) 121 is formed, the surface density of the two-dimensional electron gas 121 is usually greater than 1e¹³/cm², the resistivity of the two-dimensional electron gas 121 is relatively low, and it can be considered that the resistivity of the two-dimensional electron gas 121 is similar to the resistivity of metal.

In a composite passive component according to an embodiment of the present disclosure, an isolation part is set around the two-dimensional electron gas with a specific pattern, that is, an isolation part is formed around the two-dimensional electron gas with the specific pattern in the epitaxial structure 12, and the isolation part is used to define a specific pattern area corresponding to the two-dimensional electron gas.

Optionally, in a composite passive component according to an embodiment of the present disclosure, the specific pattern presented by the two-dimensional electron gas with the specific pattern is adaptively set with the passive component body, for example, the passive component body is a flat plate capacitor, and the specific pattern of the two-dimensional electron gas is in a flat plate shape; for example, the passive component body is a spiral inductor, and the specific pattern of the two-dimensional electron gas is in spiral shape.

The passive component being a capacitor structure

FIG. 1 is a structural schematic diagram of a composite capacitor according to an embodiment of the present disclosure, referring to FIG. 1, the composite capacitor includes: a substrate 11; an epitaxial structure 12, set on the substrate 11, a two-dimensional electron gas 121 being formed in the epitaxial structure 12; a first interlayer dielectric layer 13, covering the epitaxial structure 12; a metal capacitor structure 14, set on a side, away from the substrate 11, of the epitaxial structure 12, where the metal capacitor structure 14 includes a first metal plate 141 and a second metal plate 143, the second metal plate 143 is located on a side, away from the substrate 11, of the first metal plate 141, and the first metal plate 141 is insulated from the two-dimensional electron gas 121; along a thickness direction X of the composite capacitor, a total projection, on the substrate 11, of the first metal plate 141 and the second metal plate 143 at least partially overlaps with a projection, on the substrate 11, of the two-dimensional electron gas 121.

The surface density of the two-dimensional electron gas 121 is usually greater than 1e¹³/cm², the resistivity of the two-dimensional electron gas 121 is relatively low, and it can be considered that the resistivity of the two-dimensional electron gas 121 is similar to the resistivity of metal, that is, the two-dimensional electron gas 121 may be equivalent to a metal plate of a capacitor. As shown in FIG. 1, since the first metal plate 141 and the second metal plate 143 need to be lead out an electrode respectively, it may be set that the projection, on the substrate 11, of the first metal plate 141 does not completely overlap with the projection, on the substrate 11, of the second metal plate 143, that is, the total projection, on the substrate 11, of the first metal plate 141 and the second metal plate 143 is located in three areas on the substrate 11, a projection in a first area 111 only includes the projection of the first metal plate 141, a projection in a second area 112 includes both the projection of the first metal plate 141 and the projection of the second metal plate 143, and a projection in a third area 113 only includes the projection of the second metal plate 143. When the projection, on the substrate 11, of the two-dimensional electron gas 121 is located in the first area 111 and/or the second area 112, the two-dimensional electron gas 121 and the first metal plate 141 constitute a capacitor; when the projection, on the substrate 11, of the two-dimensional electron gas 121 is located in the third area 113 and is not connected with the second metal plate 143, the two-dimensional electron gas 121 and the second metal plate 143 constitute a capacitor, and the two-dimensional electron gas 121 is set in a thickness direction of the metal capacitor structure 14, which does not increase an occupied wafer area, therefore, the present embodiment can improve the number of capacitors and increase the integration level of the capacitor without increasing the occupied wafer area.

In the technical solution of this embodiment, the adopted composite capacitor includes: a substrate; an epitaxial structure, set on the substrate, where a two-dimensional electron gas is formed in the epitaxial structure; a metal capacitor structure, set on a side, away from the substrate, of the epitaxial structure, where the metal capacitor structure includes a first metal plate and a second metal plate, the second metal plate is located on a side, away from the substrate, of the first metal plate, and the first metal plate is insulated from the two-dimensional electron gas; and along a thickness direction of the composite capacitor, a total projection, on the substrate, of the first metal plate and the second metal plate at least partially overlaps with a projection, on the substrate, of the two-dimensional electron gas. The two-dimensional electron gas can be equivalent to one electrode plate of the capacitor, which can improve the number of capacitors and increase the integration level of the capacitor without increasing the occupied wafer area.

In an embodiment, continue to refer to FIG. 1, an isolation part 122 is formed in the epitaxial structure 12, and the isolation part 122 defines an area corresponding to the two-dimensional electron gas 121.

Specifically, in this embodiment, it may be set that a part, except the part where the two-dimensional electron gas 121 need to be retained, of the epitaxial structure 12 forms an isolation part 122, for example, it may be set that along the thickness direction of the composite capacitor, the superposition of the projection, on the substrate, of the first metal plate 141 and the projection, on the substrate 11, of the second metal plate 143 completely overlaps with the projection, on the substrate 11, of the two-dimensional electron gas 121, and the other part of the epitaxial structure 12 forms the isolation part 122, for example, the isolation part 122 may be formed by ion implantation, such as implantation of argon ions and the like, so that the resistance of the isolation part 122 is extremely high, thereby reducing substrate loss.

In an embodiment, continue to refer to FIG. 1, the composite capacitor further includes a protective layer 17 covering the second metal plate 143.

Specifically, the protective layer 17 may be, for example, one or a combination of silicon oxide, aluminum oxide, silicon nitride, silicon oxynitride, or any other material that can be used as an insulating medium. The protective layer 17 can protect the composite capacitor, prevent the composite capacitor from being corroded by external water and oxygen, and prolong the service life of the composite capacitor.

In an embodiment, as shown in FIG. 1, the two-dimensional electron gas 121 is insulated from the second metal plate 143. In this embodiment, the two-dimensional electron gas 121 can form a capacitor with the metal plate whose projection overlaps with the projection of the two-dimensional electron gas 121, preferably, it may be set that the projection, on the substrate 11, of the two-dimensional electron gas 121 is located in the first area 111 and/or the second area 112, but is not located in the third area 113, at this time, the first metal plate 141 and the two-dimensional electron gas 121 constitute a capacitor, and the first metal plate 141 and the second metal plate 143 constitute a capacitor, the composite capacitor includes two capacitors, the integration level of the capacitor is high. The two-dimensional electron gas 121 may be electrically connected with an external circuit by providing an electrode in ohmic contact with the two-dimensional electron gas 121, the position of the electrode thereof is not specifically limited. For example, the electrode may be set on a side, away from the substrate 11, of the two-dimensional electron gas 121, or may be set on a side, close to the substrate 11, of the two-dimensional electron gas 121. In some other embodiments, if the projection, on the substrate 11, of the two-dimensional electron gas 121 is located in the third area 113, but is absent in the first area 111 and the second area 112, the two-dimensional electron gas 121 and the second metal plate 143 constitute a capacitor, and the composite capacitor still includes two capacitors. In some other embodiments, if the projection, on the substrate 11, of the two-dimensional electron gas 121 is located in the third area 113 and at least one of the first area 111 and the second area 112, the two-dimensional electron gas 121 and the first metal plate 141 constitute a capacitor, the two-dimensional electron gas 121 and the second metal plate 143 also constitute a capacitor, the composite capacitor includes three capacitors, the integration level of the capacitor is further increased, and at this time, it may be preferable that the projection, on the substrate 11 of the two-dimensional electron gas 121 covers the projection, on the substrate 11, of the first metal plate 141 and the projection, on the substrate 11, of the second metal plate 143, the capacitance values of the two capacitors formed by the two-dimensional electron gas 121 in the composite capacitor are both relatively large, and the capacitance density of the composite capacitor is also relatively large.

In an embodiment, the two-dimensional electron gas 121 is configured to be equipotential with the second metal plate 143; along the thickness direction of the composite capacitor, the projection, on the substrate 11, of the first metal plate 141 at least partially overlaps with the projection, on the substrate 11, of the two-dimensional electron gas 121. Setting in this way, the two-dimensional electron gas 121 and the second metal plate 143 are equivalent to plates, which respectively overlap with two surfaces of the first metal plate 141, on the one hand, the integration level of the capacitor can be improved, on the other hand, it is equivalent to increasing the capacitance value of the composite capacitor, thereby increasing the capacitance density.

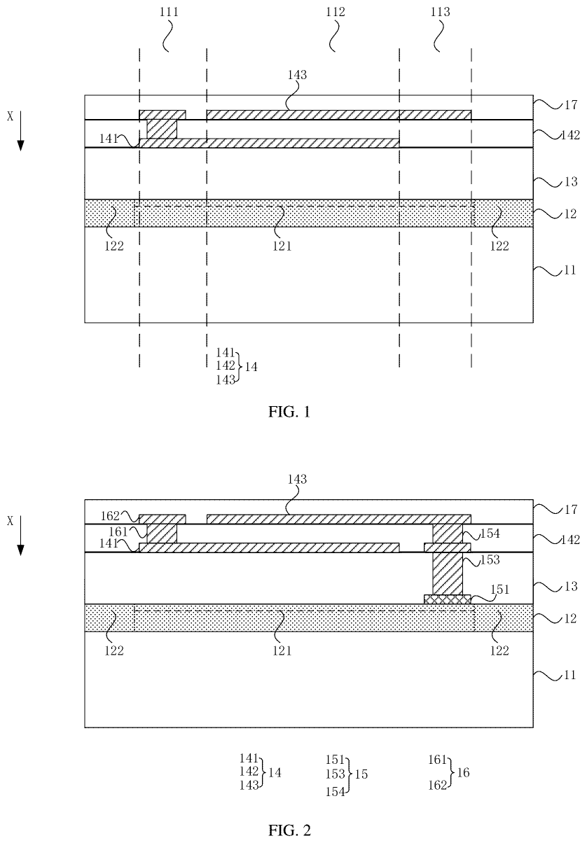

Exemplarily, FIG. 2 is a structural schematic diagram of a composite capacitor according to another embodiment of the present disclosure. In this embodiment, the composite capacitor further includes a connecting structure 15, the connecting structure 15 is in ohmic contact with the two-dimensional electron gas 121 and is electrically connected with the second metal plate 143. By forming an ohmic contact between the two-dimensional electron gas 121 and the connecting structure 15, the contact resistance is extremely low, so that the charge can be introduced into the connecting structure 15 from the two-dimensional electron gas 121. The connecting structure 15 is electrically connected with the second metal plate 143 and is insulated from the first metal plate 141. Since the projection, on the substrate 11, of the two-dimensional electron gas 121 overlaps with the projection, on the substrate 11, of the first metal plate 141 along the thickness direction X of the composite capacitor, and the two-dimensional electron gas 121 is insulated from the first metal plate 141, the two-dimensional electron gas 121 and the first metal plate 141 constitute a capacitor, and the capacitor is set as a capacitor C1; the metal capacitor structure 14 is set as a capacitor C2, the capacitor C2 and the capacitor C1 share one plate (the first metal plate 141, an upper surface and a lower surface of the first metal plate 141 both have movable charges when the composite capacitor works), and plates (the two-dimensional electron gas 121 and the second metal plate 143) that are not shared by the capacitor C1 and the capacitor C2 are electrically connected through the connecting structure 15, which is equivalent to the capacitor C1 being connected in parallel with the capacitor C2, that is, a capacitance value of the composite capacitor is equal to a sum of a capacitance value of the capacitor C1 and a capacitance value of the capacitor C2, which is equivalent to increasing the effective area of the plate of the capacitor, and the two-dimensional electron gas 121 is set in the thickness direction of the metal capacitor structure 14, the occupied wafer area is not increased, therefore, the capacitance value of the composite capacitor can be improved under the condition that the occupied wafer area is not increased. Moreover, since required metal layers are relatively few, the fabricating difficulty and the cost can be reduced.

Certainly, in some other embodiments, other solutions may also be used to implement equipotential between the two-dimensional electron gas 121 and the second metal plate 143, for example, the two-dimensional electron gas 121 and the second metal plate 143 may be electrically connected at the outside of the composite capacitor.

In an embodiment, as shown in FIG. 1 and FIG. 2, the composite capacitor further includes a first interlayer dielectric layer 13, covering the epitaxial structure 12; where the metal capacitor structure 14 includes a first metal plate 141, a second metal plate 143, and a second interlayer dielectric layer 142. The second interlayer dielectric layer 142 is set between the first metal plate 141 and the second metal plate 143, and the performance of the capacitor can be enhanced by setting the first interlayer dielectric layer 13 and the second interlayer dielectric layer 142. The metal capacitor structure 14 is a MIM capacitor at this time.

In an embodiment, continue to refer to FIG. 2, along the thickness direction X of the composite capacitor, the projection, on the substrate 11, of the two-dimensional electron gas 121 covers the projection, on the substrate 11, of the first metal plate 141 and the projection, on the substrate 11, of the second metal plate 143.

Specifically, the larger an overlapping area between the two-dimensional electron gas 121 and the first metal plate 141, the larger the capacitance value of the capacitor C1, so that it may be set that the projection, on the substrate 11, of the two-dimensional electron gas 121 covers the projection, on the substrate 11, of the first metal plate 141 along the thickness direction X of the composite capacitor, thereby increasing the capacitance value of the capacitor C1 to a greater extent. In the metal capacitor structure 14, since a lead-out electrode of the MIM capacitor needs to be set, the projection, on the substrate 11, of the second metal plate 143 does not completely overlap with the orthographic projection, on the substrate 11, of the first metal plate 141 along the thickness direction X of the composite capacitor, so that it may be set that the projection, on the substrate 11, of the two-dimensional electron gas 121 covers the orthographic projection, on the substrate 11, of the second metal plate 143 along the thickness direction X of the composite capacitor, thereby facilitating the set of the connecting structure 15.

It should be noted that, as shown in FIG. 1 and FIG. 2, the composite capacitor may further include a first electrode 16. The first electrode 16 is located on a side, away from the substrate 11, of the first metal plate 141 and is electrically connected with the first metal plate 141, and a part, penetrating through the second interlayer dielectric layer 142, of the connecting structure 15 may be used as a second electrode of the composite capacitor.

Exemplarily, as shown in FIG. 2, the connecting structure 15 includes a connecting metal layer 151 and a connecting metallized through hole; the connecting metal layer 151 is in contact with a surface of the two-dimensional electron gas; and the connecting metallized through hole penetrates through the first interlayer dielectric layer 13 and the second interlayer dielectric layer 142 to be electrically connected with the connecting metal layer 151 and the second metal plate 143.

Specifically, in this embodiment, the connecting metal layer 151 is directly in ohmic contact with the two-dimensional electron gas 121, when the composite capacitor is fabricated, the connecting metal layer 151 may be directly fabricated after the epitaxial structure 12 is formed by epitaxy, and the contact performance of the connecting metal layer 151 and the two-dimensional electron gas 121 is better, which is more beneficial to improving the performance of the composite capacitor. A first through hole penetrates through the first interlayer dielectric layer 13, a second through hole penetrates through the second interlayer dielectric layer 142, the connecting metallized through hole includes a first sub through hole 153 and a second sub through hole 154, the first sub through hole 153 is the first through hole after metallization, and the second sub through hole 154 is the second through hole after metallization. The connecting metal layer 151, for example, may be formed by first depositing a composite metal by using an electron beam evaporation system, and then forming the connecting metal layer by using a rapid thermal annealing (RTA) process. The connecting metallized through hole may be formed by etching a through hole, and then metallizing the through hole.

In some other embodiments, as shown in FIG. 3, FIG. 3 is a structural schematic diagram of a composite capacitor according to another embodiment of the present disclosure. Unlike the structure shown in FIG. 2, the connecting structure 15 of this embodiment includes a connecting metal layer 151, an ohmic metallized through hole 152 and a connecting metallized through hole; the connecting metal layer 151 and the first metal plate 141 are set in a same layer, the connecting metal layer 151 is in ohmic contact with the two-dimensional electron gas 121 through the ohmic metallized through hole 152 penetrating through the first interlayer dielectric layer 13; and the connecting metallized through hole penetrates through the second interlayer dielectric layer 142 to be electrically connected with the connecting metal layer 151 and the second metal plate 143.

Specifically, in this embodiment, the connecting metal layer 151 and the first metal plate 141 are set in the same layer, after the epitaxial structure 12 is formed by epitaxy, the first interlayer dielectric layer 13 may be grown first, then a through hole is etched in the first interlayer dielectric layer 13, then the connecting metal layer 151 and the ohmic metallized through hole 152 are simultaneously fabricated by using an ohmic metal fabricating process. A fourth through hole penetrates through the second interlayer dielectric layer 142, the connecting metallized through hole only includes the second sub through hole 154, and in this embodiment, the second sub through hole 154 is the fourth through hole after metallization.

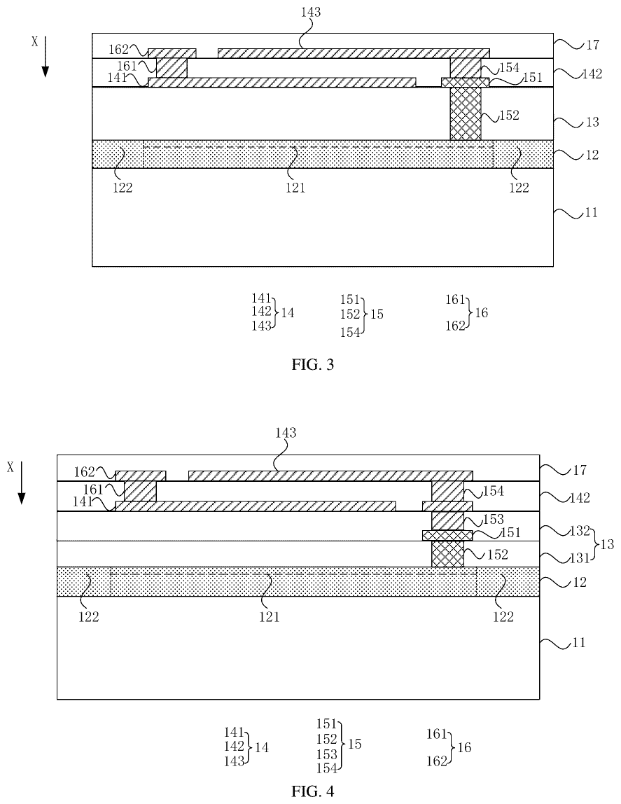

In some other embodiments, as shown in FIG. 4, FIG. 4 is a structural schematic diagram of a composite capacitor according to another embodiment of the present disclosure. Unlike the structure shown in FIG. 2 and FIG. 3, the connecting structure 15 of this embodiment includes a connecting metal layer 151, an ohmic metallized through hole 152 and a connecting metallized through hole; the first interlayer dielectric layer 13 includes a first sub dielectric layer 131 and a second sub dielectric layer 132 which are stacked on the epitaxial structure 12; the connecting metal layer 151 is set on a surface, away from the epitaxial structure 12, of the first sub dielectric layer 131, and is in ohmic contact with the two-dimensional electron gas 121 through the ohmic metallized through hole 152 penetrating through the first sub dielectric layer 131; and the connecting metallized through hole penetrates through the second interlayer dielectric layer 142 and the second sub dielectric layer 132 to be electrically connected with the connecting metal layer 151 and the second metal plate 143.

Specifically, in this embodiment, the first interlayer dielectric layer 13 includes the first sub dielectric layer 131 and the second sub dielectric layer 132, a material of the first sub dielectric layer 131 and a material of the second sub dielectric layer 132 may be, for example, one or a combination of silicon oxide, aluminum oxide, silicon nitride, silicon oxynitride, or any other material that can be used as an insulating medium. The composite capacitor may be fabricated on a same wafer with other thin film device, such as a thin film transistor, or the like, and the connecting metal layer 151 is set on the first sub dielectric layer 131, which may be compatible with other devices on the wafer, thereby improving the compatibility of the composite capacitor fabricating process. A sixth through hole penetrates through the second sub dielectric layer 132, a seventh through hole penetrates through the second interlayer dielectric layer 142, the connecting metallized through hole includes a first sub through hole 153 and a second sub through hole 154, in this embodiment, the first sub through hole 153 is the sixth through hole after metallization, and the second sub through hole 154 is the seventh through hole after metallization.

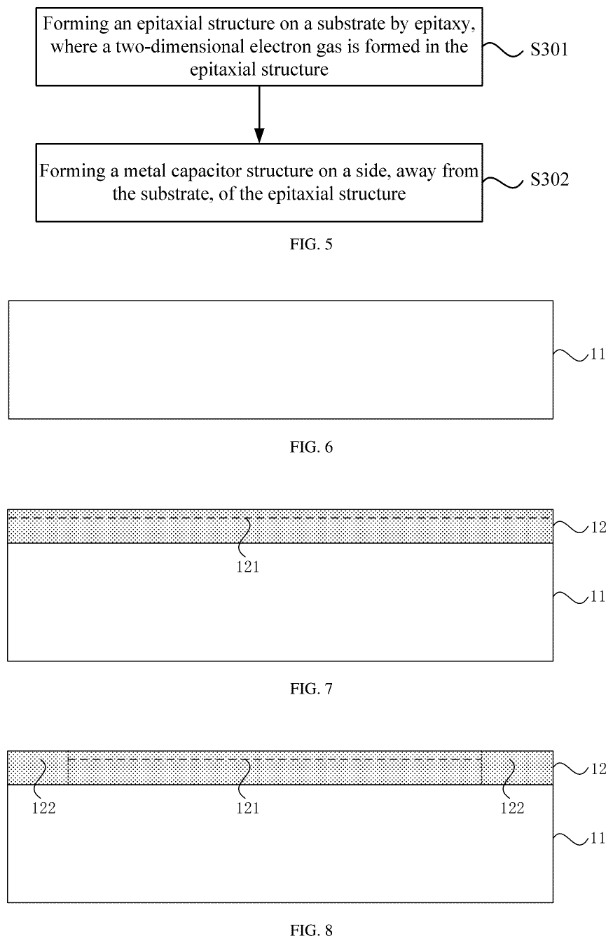

An embodiment of the present disclosure further provides a preparation method for a composite capacitor, as shown in FIG. 5, FIG. 5 is a flowchart of a preparation method for a composite capacitor according to an embodiment of the present disclosure, the preparation method includes Step S301 and Step S302.

Step S301, Forming an epitaxial structure on a substrate by epitaxy, where a two-dimensional electron gas is formed in the epitaxial structure.

Specifically, FIG. 6 to FIG. 15 are structural schematic diagrams of products corresponding to main processes of a preparation method for a composite capacitor according to an embodiment of the present disclosure. As shown in FIG. 6, a substrate 11 may be provided first; subsequently, as shown in FIG. 7, an epitaxial structure 12 is formed on the substrate 11 by epitaxy. The growing method, for example, may be any one of metal organic chemical vapor deposition (MOCVD), molecular beam epitaxy (MBE), and hydride vapor phase epitaxy (HVPE). The epitaxial structure 12 may include multiple layers, a material of each layer structure may be a semiconductor material based on a group III-V compound, and the epitaxial structure 12 may be, for example, a heterojunction. After the epitaxial structure 12 is grown and formed, a layer of two-dimensional electron gas 121 may be formed inside the epitaxial structure 12, the two-dimensional electron gas 121 may be used to form a plate of the capacitor; subsequently, as shown in FIG. 8, in order to reduce substrate loss, a part, except the part where the two-dimensional electron gas 121 need to be retained, of the epitaxial structure 12 forms an isolation part 122, the isolation part 122 may be formed, for example, by ion implantation, such as implantation of argon ions and the like, so that the resistance of the isolation part 122 is extremely high, thereby reducing the substrate loss.

Step S302, Forming a metal capacitor structure on a side, away from the substrate, of the epitaxial structure, where the metal capacitor structure includes a first metal plate and a second metal plate, the second metal plate is located on a side, away from the substrate, of the first metal plate, and the first metal plate is insulated from the two-dimensional electron gas; and along a thickness direction of the composite capacitor, a total projection, on the substrate, of the first metal plate and the second metal plate at least partially overlaps with a projection, on the substrate, of the two-dimensional electron gas.

The composite capacitor prepared by the preparation method for the composite capacitor according to the embodiment, the two-dimensional electron gas and at least one of the first metal plate and the second metal plate form a capacitor, and the two-dimensional electron gas is set in a stacking direction of the first metal plate and the second metal plate, so that the number of capacitors in the composite capacitor can be increased without increasing the wafer area occupied by the composite capacitor, thereby improving the integration level of the capacitor.

In an embodiment, the forming a metal capacitor structure on a side, away from the substrate, of the epitaxial structure includes: forming a first metal plate, so that a projection, on the substrate, of the first metal plate at least partially overlaps with a projection, on the substrate, of the two-dimensional electron gas along the thickness direction of the composite capacitor; when forming the metal capacitor structure on the side, away from the substrate, of the epitaxial structure, the preparation method further includes: forming a connecting structure, where the connecting structure is in ohmic contact with the two-dimensional electron gas and is electrically connected with the second metal plate.

Exemplarily, when forming the metal capacitor structure, the first interlayer dielectric layer may further be formed. The first interlayer dielectric layer covers the epitaxial structure; the metal capacitor structure is set on a side, away from the substrate, of the first interlayer dielectric layer, The metal capacitor structure includes the first metal plate, the second metal plate and a second interlayer dielectric layer, and the second metal plate is located on the side, away from the substrate, of the first metal plate. The connecting structure includes a connecting metal layer and a connecting metallized through hole; and forming a first interlayer dielectric layer, a metal capacitor structure and a connecting structure includes the following contents.

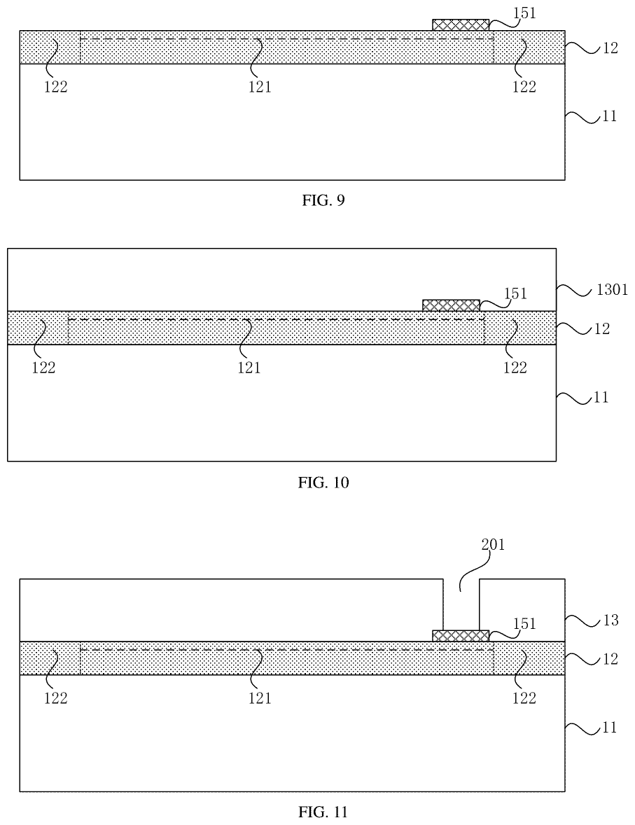

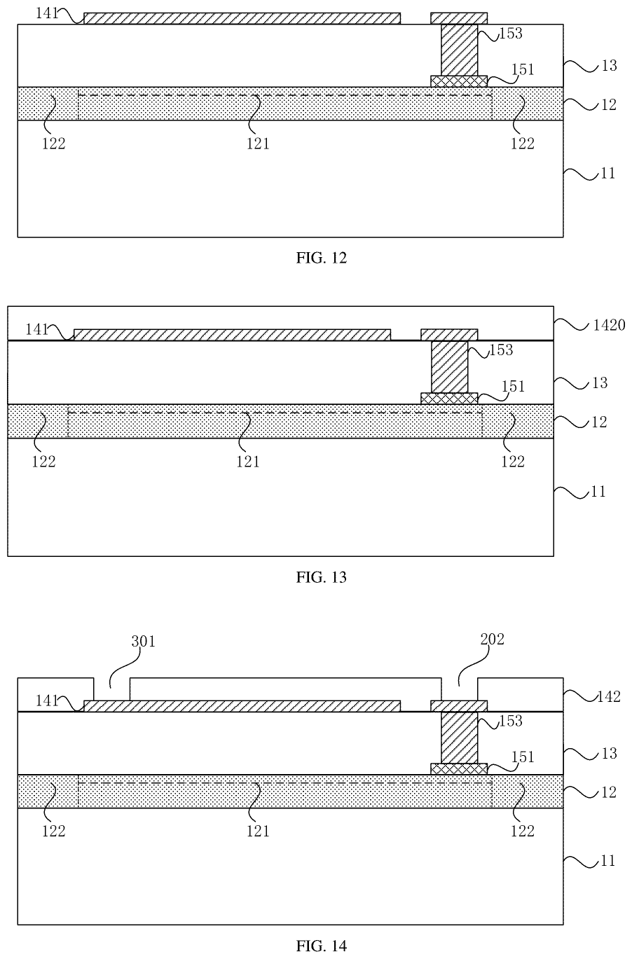

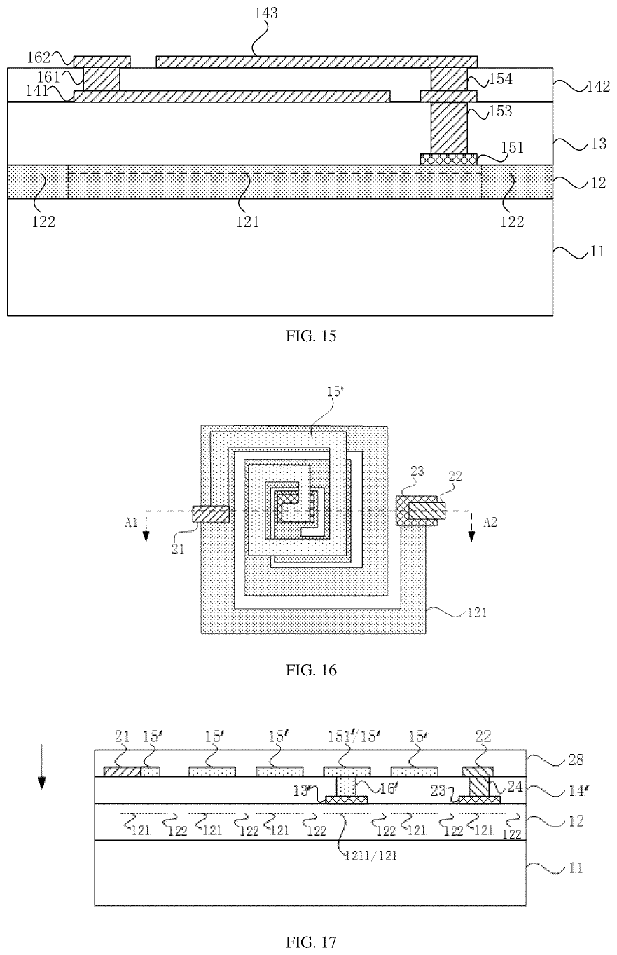

As shown in FIG. 9, a connecting metal layer 151 is formed on a surface, away from the substrate 11, of the epitaxial structure 12; specifically, a composite metal is first deposited by using an electron beam evaporation system, and then the connecting metal layer is formed by using a rapid thermal annealing (RTA) process; subsequently as shown in FIG. 10, a layer of dielectric layer material is first grown, the dielectric layer material may be, for example, one or a combination of silicon oxide, aluminum oxide, silicon nitride, silicon oxynitride, or any other material that can be used as an insulating medium; next, as shown in FIG. 11, a first through hole 201 is formed by exposing, developing, etching, and the like, and the first through hole 201 exposes the connecting metal layer 151; next, as shown in FIG. 12, the first metal plate 141 is formed on the surface, away from the substrate, of the first interlayer dielectric layer 13, and the first through hole is metallized, for example, the first metal plate 141 may be fabricated by sputtering, deposition, or the like, and be formed through a mask, and the first through hole is metallized at the same time to form the first sub through hole 153; next, as shown in FIG. 13, a whole surface is covered with a layer of dielectric layer material 1420 as an isolation layer of the metal capacitor structure, the dielectric layer material 1420 may be one or a combination of silicon oxide, aluminum oxide, silicon nitride, silicon oxynitride, or any other material that can be used as an insulating medium; next, as shown in FIG. 14, a second through hole 202 is formed by exposure and development etching, or the like, and the second through hole 202 exposes the first through hole; in addition, an electrode through hole 301 may also be formed at the same time, and the electrode through hole 301 may be used to subsequently form a metal electrode, thereby forming the second interlayer dielectric layer 142 in FIG. 14; next, as shown in FIG. 15, the second metal plate 143 may be fabricated by sputtering, deposition, or the like, and be formed through a mask, the second through hole 202 and the electrode through hole 301 may be metallized at the same time to form a second sub through hole 154, a second metal plate 143, an electrode metal through hole 161, and an electrode 162, where the electrode metal through hole 161 and the electrode 162 constitute a first electrode of the composite capacitor, and a part, penetrating through the second interlayer dielectric layer 142, of the connecting structure 15 may be used as a second electrode of the composite capacitor. Finally, as shown in FIG. 2, a whole surface is covered with a protective layer 17 to form the structure shown in FIG. 2, and the protective layer 17 may be, for example, one or a combination of silicon oxide, aluminum oxide, silicon nitride, silicon oxynitride, or any other material that can be used as an insulating medium. The protective layer 17 can protect the composite capacitor, prevent the composite capacitor from being corroded by external water and oxygen, and prolong the service life of the composite capacitor.

In an embodiment, unlike the above preparation method, the connecting structure in this embodiment includes a connecting metal layer, an ohmic metallized through hole and a connecting metallized through hole; and forming the first interlayer dielectric layer, the metal capacitor structure and the connecting structure includes the following contents.

After forming the structure shown in FIG. 8, a material 1301 of the first interlayer dielectric layer may be first deposited on the epitaxial structure 12, the material of the first interlayer dielectric layer may be, for example, one or a combination of silicon oxide, aluminum oxide, silicon nitride, silicon oxynitride, or any other material that can be used as an insulating medium; then a third through hole 203 is formed by exposing, developing, etching, and the like, and the third through hole 203 exposes an area corresponding to the connecting metal layer; then the connecting metal layer 151 is formed on a surface, away from the substrate, of the first interlayer dielectric layer 13, and the third through hole is metallized to form an ohmic metallized through hole 152, the connecting metal layer 151 is in ohmic contact with the two-dimensional electron gas 121 through the ohmic metallized through hole 152, and the connecting metal layer 151 and the ohmic metallized through hole 152 are fabricated simultaneously by using an ohmic metal fabricating process, the ohmic metal fabricating process may be: a composite metal is first deposited by using an electron beam evaporation system, and then an ohmic metal is formed by using a rapid thermal annealing process; then, since the high-temperature process is required during preparation of the connecting metal layer, the connecting metal layer may be fabricated first, then the first metal plate 141 may be fabricated, and the first metal plate 141 may be fabricated by sputtering, deposition, etc.; in addition, in order to prevent the first metal plate from being electrically connected with the connecting metal layer, a sacrificial layer may be fabricated on the connecting metal layer before depositing the whole metal layer, and then the sacrificial layer is etched away after the metal layer is etched to form the first metal plate 141, so that the first metal plate 141 and the connecting metal layer 151 are formed on a same layer; subsequently a whole surface is covered with a layer of dielectric layer material 1420 as an isolation layer of the metal capacitor structure, the dielectric layer material 1420 may be one or a combination of silicon oxide, aluminum oxide, silicon nitride, silicon oxynitride, or any other material that can be used as an insulating medium; next, a fourth through hole 204 is formed by exposing, developing, etching, and the like, and the fourth through hole 204 exposes the connecting metal layer 151; in addition, an electrode through hole 301 may also be formed at the same time, and the electrode through hole 301 may be used to subsequently form a metal electrode, thereby forming the second interlayer dielectric layer 142 in FIG. 20; the second metal plate 143 may be fabricated by sputtering, deposition, etc., and be formed through a mask, the fourth through hole 204 and the electrode through hole 301 may be metallized at the same time to form a second sub through hole 154, a second metal plate 143, an electrode metal through hole 161, and an electrode 162. Finally, as shown in FIG. 2, a whole surface is covered with the protective layer 17 to form the structure shown in FIG. 3, the protective layer 17 may be, for example, one or a combination of silicon oxide, aluminum oxide, silicon nitride and silicon oxynitride, or any other material capable of being used as an insulating medium. The protective layer 17 can protect the composite capacitor, prevent the composite capacitor from being corroded by external water and oxygen, and prolong the service life of the composite capacitor.

In an embodiment, unlike the above preparation method, the connecting structure in this embodiment includes a connecting metal layer, an ohmic metallized through hole, and a connecting metallized through hole; the first interlayer dielectric layer includes a first sub dielectric layer and a second sub dielectric layer; and forming the first interlayer dielectric layer, the metal capacitor structure, and the connecting structure includes the following contents.

After forming the structure shown in FIG. 8, a material 1310 of the first sub dielectric layer may be first deposited on the epitaxial structure 12, the material 1310 of the first sub dielectric layer may be, for example, one or a combination of silicon oxide, aluminum oxide, silicon nitride, silicon oxynitride, or any other material that can be used as an insulating medium; a fifth through hole 205 is formed by exposing, developing, etching, and the like, and the fifth through hole 205 exposes an area corresponding to the connecting metal layer; a connecting metal layer 151 is formed on a surface, away from the substrate, of the first sub dielectric layer 131, and the fifth through hole is metallized to form an ohmic metallized through hole 152, the connecting metal layer 151 is in ohmic contact with the two-dimensional electron gas 121 through the ohmic metallized through hole 152, and a connecting metal layer 151 and an ohmic metallized through hole 152 are fabricated simultaneously by using an ohmic metal fabricating process, the ohmic metal fabricating process may be: a composite metal is first deposited by using an electron beam evaporation system, and then an ohmic metal is formed by using a rapid thermal annealing process; and a whole surface is covered with a material 1320 of the second sub dielectric layer, the material of the second sub dielectric layer may be, for example, one or a combination of silicon oxide, aluminum oxide, silicon nitride, silicon oxynitride, or any other material that can be used as an insulating medium; a sixth through hole 206 is formed by exposing, developing, etching, and the like, and the sixth through hole 206 exposes the connecting metal layer 151; the first metal plate 141 is formed on a surface, away from the substrate, of the second sub dielectric layer 132, and the sixth through hole is metallized, for example, the first metal plate 141 may be fabricated by sputtering, deposition, etc., and be formed through a mask, and the sixth through hole is metallized at the same time to form the first sub through hole 153; a whole surface is covered with the dielectric layer material 1420 as an isolation layer of the metal capacitor structure, the dielectric layer material 1420 may be one or a combination of silicon oxide, aluminum oxide, silicon nitride, silicon oxynitride, or any other material that can be used as an insulating medium; a seventh through hole 207 is formed by exposing, developing, etching, and the like, and the seventh through hole 207 exposes the sixth through hole 206; in addition, an electrode through hole 301 may also be formed at the same time, and the electrode through hole 301 may be used to subsequently form a metal electrode, thereby forming the second interlayer dielectric layer 142; the second metal plate 143 may be fabricated by sputtering, deposition, etc., and be formed through a mask, the seventh through hole 207 and the electrode through hole 301 may be metallized at the same time to form a second sub through hole 154, a second metal plate 143, an electrode metal through hole 161, and an electrode 162. Finally, as shown in FIG. 4, a whole surface is covered with the protective layer 17 to form the structure shown in FIG. 3, the protective layer 17 may be, for example, one or a combination of silicon oxide, aluminum oxide, silicon nitride and silicon oxynitride, or any other material capable of being used as an insulating medium. The protective layer 17 can protect the composite capacitor, prevent the composite capacitor from being corroded by external water and oxygen, and prolong the service life of the composite capacitor.

The passive component being an inductor structure

FIG. 16 is a top view of a composite inductor according to an embodiment of the present disclosure. FIG. 17 is a cross-sectional view along the A1A2 direction in FIG. 16. Referring to FIG. 16 and FIG. 17, the composite inductor includes: a substrate 11; an epitaxial structure 12, set on the substrate 11, a two-dimensional electron gas 121 being formed in the epitaxial structure 12, and the two-dimensional electron gas 121 being in a first planar spiral shape; a first connecting metal layer 13′, being in ohmic contact with a first end of the two-dimensional electron gas 121; an inductive metal wire 15′, set on a side, away from the substrate 11, of the epitaxial structure 12, and the inductive metal wire 15′ being in a second planar spiral shape; a first connecting metal 16′, where a first end of the first connecting metal 16′ is electrically connected with the first connecting metal layer 13′, and a second end of the first connecting metal 16′ is electrically connected with a first end of the inductive metal wire 15′. The first end 151′ of the inductive metal wire 15′ is one end, corresponding to a center point of the second planar spiral shape, of the inductive metal wire 15′; and the first end 1211 of the two-dimensional electron gas 121 is one end, corresponding to a center point of the first planar spiral shape, of the two-dimensional electron gas 121.

The two-dimensional electron gas 121 may be equivalent to a metal wire of an inductor, and the two-dimensional electron gas 121 is set to be in the first planar spiral shape, that is, the two-dimensional electron gas 121 may be equivalent to one inductor, and the inductor is set as a first inductor; at the same time, since the first connecting metal layer 13′ is in ohmic contact with the two-dimensional electron gas 121, the contact resistance is extremely low, so that the current can be transmitted from the first connecting metal 16′ to the two-dimensional electron gas 121, or the current can be transmitted from the two-dimensional electron gas 121 to the first connecting metal 16′. Since the inductive metal wire 15′ is configured to be in the second planar spiral shape, the inductive metal wire 15′ is also equivalent to one inductor, and the inductor is set to be a second inductor, a spiral direction of the first inductor is opposite to a spiral direction of the second inductor, and a total inductance of the composite inductor is a series of the first inductor and the second inductor, so it is equivalent to increasing the inductance of the composite inductor. In addition, since the first planar spiral is spiral outward with its center point as a center, the second planar spiral is spiral outward with its center point as a center, under a condition that the size of the wafer occupied by the composite inductor is unchanged, the first inductor and the second inductor of the composite inductor are respectively set on different layers, and are in series to increase the inductance of the composite inductor, that is, the length of the current path on a unit wafer area is increased, thereby increasing the inductance density of the composite inductor.

In the technical solution of this embodiment, the adopted composite inductor includes a substrate; an epitaxial structure, set on the substrate, where a two-dimensional electron gas is formed in the epitaxial structure, and the two-dimensional electron gas is in the first planar spiral shape; a first connecting metal layer, where the first connecting metal layer is in ohmic contact with a first end of the two-dimensional electron gas; an inductive metal wire, set on a side, away from the substrate, of the epitaxial structure, the inductive metal wire being in the second planar spiral shape; a first connecting metal, a first end of the first connecting metal is electrically connected with the first connecting metal layer, and a second end of the first connecting metal is electrically connected with a first end of the inductive metal wire, where the first end of the inductive metal wire is one end, corresponding to a center point of the second planar spiral shape, of the inductive metal wire, the first end of the two-dimensional electron gas is one end, corresponding to a center point of the first planar spiral shape, of the two-dimensional electron gas, and a spiral direction of the first planar spiral shape is opposite to a spiral direction of the second planar spiral shape. When the size of the wafer occupied by the composite inductor is unchanged, the first inductor and the second inductor of the composite inductor are respectively set on different layers, and are in series to increase the inductance of the composite inductor that is, the length of the current path on a unit wafer area is increased, thereby increasing the inductance density of the composite inductor.

Optionally, the spiral direction of the first planar spiral shape is opposite to the spiral direction of the second planar spiral shape, so that the total inductance of the inductor composed of the inductive metal wire and the inductor composed of the two-dimensional electron gas is further increased, thereby further increasing the inductance density of the composite inductor.

It should be noted that, in FIG. 16, although the first planar spiral shape and the second planar spiral shape are rectangular spiral shape as examples for description, in some other embodiments, both the first planar spiral shape and the second planar spiral shape may be in other shapes, and the two may be the same or different, for example, the first planar spiral shape may also be a circular spiral shape, and the second planar spiral shape may also be a circular spiral shape.

Optionally, continue to refer to FIG. 16 and FIG. 17, an isolation part 122 is formed in the epitaxial structure 12, and the isolation part 122 defines an area corresponding to the two-dimensional electron gas 121.

Specifically, the two-dimensional electron gas 121 needs to form the first planar spiral shape, while there will be an whole layer of two-dimensional electron gas after the epitaxial structure 12 is formed, which makes the first planar spiral shape cannot be formed, therefore, the area corresponding to the two-dimensional electron gas 121 may be defined by setting the isolation part 122, for example, the isolation part 122 may be formed by implanting argon ions into the epitaxial structure 12, the resistance of the isolation part 122 is extremely high, which is equivalent to an insulator, thereby defining the two-dimensional electron gas 121 in the first planar spiral shape.

Optionally, continue to refer to FIG. 16, along a thickness direction of the composite inductor, a width of the two-dimensional electron gas is greater than a width of the inductive metal wire. In this way, the resistance of the two-dimensional electron gas 121 is relatively small, so that the inductor formed by the two-dimensional electron gas 121 is closer to an ideal inductor, which is beneficial to improving the performance of the inductor formed by the two-dimensional electron gas 121.

Optionally, continue to refer to FIG. 16, the number of turns of the two-dimensional electron gas 121 is greater than the number of turns of the inductive metal wire 15′.

Specifically, the number of turns of the two-dimensional electron gas 121 is also the number of turns of the first planar spiral shape, the number of turns of the inductive metal wire 15′ is also the number of turns of the second planar spiral shape, in FIG. 16, the number of turns of the first planar spiral shape is 2, and the number of turns of the second planar spiral shape is 3. The two-dimensional electron gas 121 needs to be connected with an electrode metal as one of the electrodes of the composite inductor, and the layer where the inductive metal wire 15′ is located is a metal layer, it will be easier to fabricate the electrode of the composite inductor at the layer; therefore, the number of turns of the two-dimensional electron gas 121 is greater than the number of turns of the inductive metal wire 15′, and a length of the two-dimensional electron gas 121 is longer than a length of the inductive metal wire 15′, the two-dimensional electron gas 121 will have a redundant portion to facilitate the current at the second end thereof to be introduced into the layer where the inductive metal wire 15′ is located, thereby facilitating the fabrication of the electrode of the composite inductor. It should be noted that, in FIG. 16, although the wafer area required by the two-dimensional electron gas 121 is greater than the wafer area required by the inductive metal wire 15′ as an example for description, in some other embodiments, the wafer area required by the two-dimensional electron gas 121 may also be set to be less than the wafer area required by the inductive metal wire 15′; and the number of turns of the two-dimensional electron gas 121 may also be less than the number of turns of the inductive metal wire 15′; in addition, the projection of the two-dimensional electron gas 121 on the substrate 11 and the projection, on the substrate 11, of the inductive metal wire 15′ may overlap or not overlap except for an overlapping area that cannot be avoided due to the opposite spiral directions of the two spiral shape, which is not specifically limited in this embodiments.

Optionally, continue to refer to FIG. 16 and FIG. 17, the composite inductor further includes a first interlayer dielectric layer 14′, a first electrode metal 21, a second electrode metal 22, a second connecting metal layer 23, and a second connecting metal 24. The first interlayer dielectric layer 14′ is set on the side, away from the substrate 11, of the epitaxial structure 12; the inductive metal wire 15′ is set on a side, away from the substrate 11, of the first interlayer dielectric layer 14′; the first electrode metal 21, the second electrode metal 22, and the inductive metal wire 15′ are set on a same layer, and the first electrode metal 21 is electrically connected with a second end of the inductive metal wire 15′; the second connecting metal layer 23 and the first connecting metal layer 13′ are set on a same layer, and the second connecting metal layer 23 is in ohmic contact with a second end of the two-dimensional electron gas 121; and the second connecting metal 24 penetrates through the first interlayer dielectric layer 14′, a first end of the second connecting metal 24 is electrically connected with the second connecting metal layer 23, and a second end of the second connecting metal 24 is electrically connected with the second electrode metal 22.

Specifically, all of the first electrode metal 21, the second electrode metal 22, the inductive metal wire 15′, the first connecting metal 16′, and the second connecting metal 24 may be aluminum, and may be formed simultaneously; the first connecting metal layer 13′ and the second connecting metal layer 23 may be formed simultaneously, for example, a composite metal may be first deposited by using an electron beam evaporation system, and then the first connecting metal layer 13′ and the second connecting metal layer 23 are formed by using a rapid thermal annealing (RTA) process. The first electrode metal 21 is used as a first electrode of the composite inductor, the second electrode metal 22 is used as a second electrode of the composite inductor, the current path of the composite inductor starts from the first electrode metal 21, to the second end of the inductive metal wire 15′, after passing through the inductive metal wire 15′ in the second planar spiral shape, the current flows into the first connecting metal 16′ through the first end 151′ of the inductive metal wire 15′, subsequently, the current flows into the first end 1211 of the two-dimensional electron gas 121 through the first connecting metal layer 13′, after passing through the two-dimensional electron gas 121 in the first planar spiral shape, the current flows into the second connecting metal layer 23 through the second end of the two-dimensional electron gas 121, subsequently, the current flows into the second electrode metal 22 through the second connecting metal 24; of course, in some other embodiments, the current path may also be opposite, that is, the current flows in from the second electrode metal 22, and flows out from the first electrode metal 21.

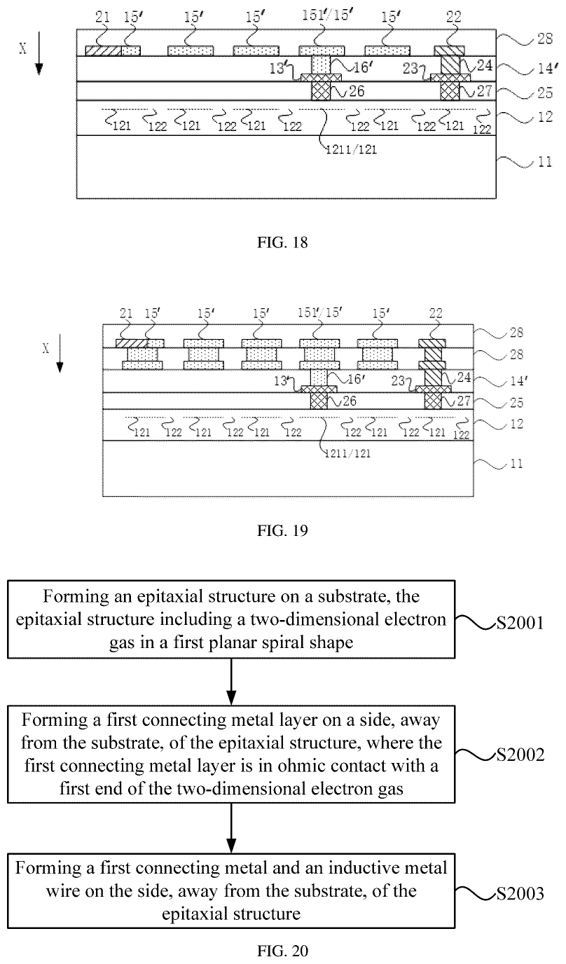

Optionally, FIG. 18 is another cross-sectional view along the A1A2 direction in FIG. 16, and referring to FIG. 16 and FIG. 18, unlike the structure shown in FIG. 17, in this embodiment, the composite inductor further includes a second interlayer dielectric layer 25, a first ohmic metallized through hole 26, and a second ohmic metallized through hole 27; the second interlayer dielectric layer 25 is set between the first interlayer dielectric layer 14′ and the epitaxial structure 12; the first ohmic metallized through hole 26 penetrates through the second interlayer dielectric layer 25, the second ohmic metallized through hole 27 penetrates through the second interlayer dielectric layer 25; the first connecting metal layer 13′ is in ohmic contact with the first end 1211 of the two-dimensional electron gas 121 through the first ohmic metallized through hole 26, and the second connecting metal layer 23 is in ohmic contact with the second end of the two-dimensional electron gas 121 through the second ohmic metallized through hole 27.

Specifically, the second interlayer dielectric layer 25 may be, for example, one or a combination of silicon oxide, aluminum oxide, silicon nitride, silicon oxynitride, or any other material that can be used as an insulating medium. The composite inductor may be fabricated on a same wafer with other thin film device, such as a thin film transistor, and the first connecting metal layer and the second connecting metal layer are set on the second interlayer dielectric layer 25, which may be compatible with other devices on the wafer, thereby improving the compatibility of the composite inductor fabricating process.

Optionally, referring to FIG. 16 to FIG. 18, the composite inductor further includes a protective layer 28, and the protective layer 28 covers the inductive metal wire 15′.

Specifically, the protective layer 28 may be, for example, one or a combination of silicon oxide, aluminum oxide, silicon nitride, silicon oxynitride, or any other material that can be used as an insulating medium. The protective layer 28 can protect the composite inductor, prevent the composite inductor from being corroded by external water and oxygen, and prolong the service life of the composite inductor.

It should be noted that FIG. 19 is another cross-sectional view along the A1A2 direction in FIG. 16, in this embodiment, the inductive metal wire 15′ is a multi-layer structure, and the corresponding protective layer 28 is also a multi-layer structure, which may be equivalent to increasing the thickness of the inductive metal wire 15′, thereby facilitating to reduce the resistance of the inductive metal wire 15′.

An embodiment of the present disclosure further provides a preparation method for a composite inductor, and FIG. 20 is a flowchart of a preparation method for a composite inductor according to an embodiment of the present disclosure. Refer to FIG. 20, the preparation method includes Step S2001 to Step S2003.

Step S2001, forming an epitaxial structure on a substrate, the epitaxial structure including a two-dimensional electron gas in a first planar spiral shape.

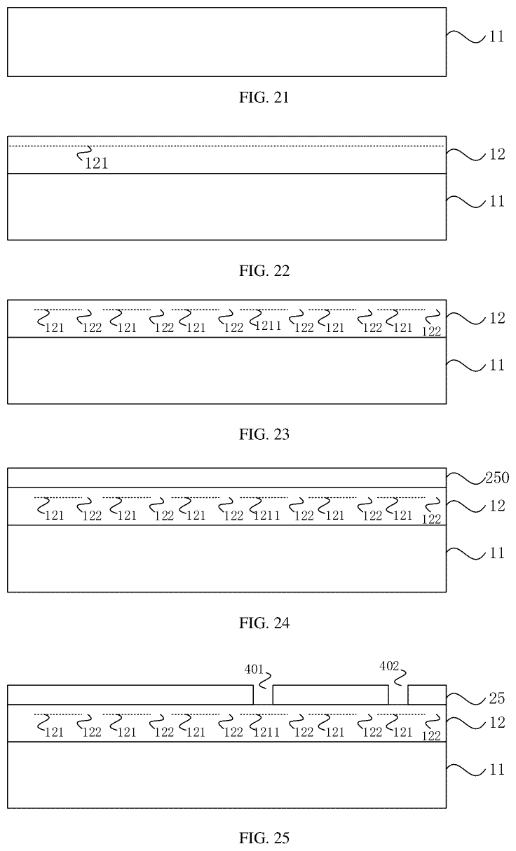

Specifically, FIG. 21 to FIG. 29 are structural schematic diagrams of products corresponding to main processes of a preparation method for a composite inductor according to an embodiment of the present disclosure. As shown in FIG. 21, a substrate 11 may be provided first; subsequently, as shown in FIG. 22, an epitaxial structure 12 is formed on the substrate 11 by epitaxy, the growing method, for example, may be any one of metal organic chemical vapor deposition (MOCVD), molecular beam epitaxy (MBE), and hydride vapor phase epitaxy (HVPE). The epitaxial structure 12 may include multiple layers, a material of each layer structure may be a semiconductor material based on a group III-V compound, and the epitaxial structure 12 may be, for example, a heterojunction. After the epitaxial structure 12 is grown and formed, a layer of two-dimensional electron gas 121 may be formed inside the epitaxial structure 12; subsequently, as shown in FIG. 23, since the two-dimensional electron gas 121 is a whole-layer structure, in order to form the two-dimensional electron gas in the first planar spiral shape, a part, except the part where the two-dimensional electron gas 121 need to be retained, of the epitaxial structure 12 forms an isolation part 122, for example, the isolation part 122 may be formed by ion implantation, such as implantation of argon ions, and the like.

Step S2002, forming a first connecting metal layer on a side, away from the substrate, of the epitaxial structure, where the first connecting metal layer is in ohmic contact with a first end of the two-dimensional electron gas.

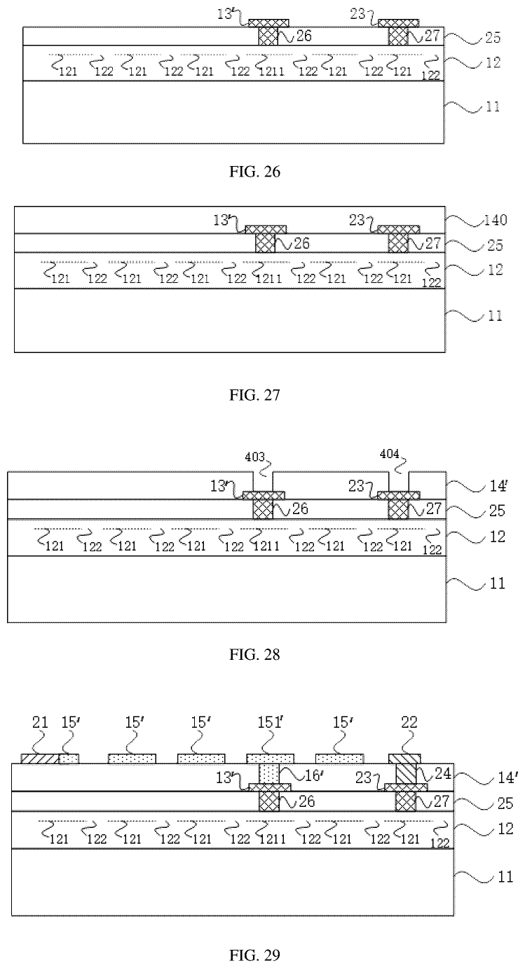

Specifically, before forming the first connecting metal layer, a second interlayer dielectric layer may be first formed on a surface, away from the substrate, of the epitaxial structure, a first ohmic through hole and a second ohmic through hole are formed in the second interlayer dielectric layer, the first ohmic through hole exposes a first end of the two-dimensional electron gas, and the second ohmic through hole exposes a second end of the two-dimensional electron gas. As shown in FIG. 24, a material 250 of the second interlayer dielectric layer is formed on an whole surface, and the material 250 of the second interlayer dielectric layer may be, for example, one or a combination of silicon oxide, aluminum oxide, silicon nitride, silicon oxynitride, or any other material that can be used as an insulating medium; next, as shown in FIG. 25, a first ohmic through hole 401 and a second ohmic through hole 402 are formed by exposing, developing, etching, and the like; next, as shown in FIG. 26, a first connecting metal layer 13′ and a second connecting metal layer 23 are formed on a surface, away from the substrate, of the second interlayer dielectric layer 25, and the first ohmic through hole 401 is metallized to form a first ohmic metallized through hole 26, and the second ohmic through hole 402 is metallized to form a second ohmic metallized through hole 27; the first connecting metal layer 13′ is in ohmic contact with a first end of the two-dimensional electron gas 121 through the first ohmic metallized through hole 26, the second connecting metal layer 23 is in ohmic contact with a second end of the two-dimensional electron gas 121 through the second ohmic metallized through hole 27, the connecting metal layer and the ohmic metallized through hole are fabricated by using an ohmic metal fabricating process, the ohmic metal fabricating process may be: first depositing a composite metal by using an electron beam evaporation system, and then forming an ohmic metal by using a rapid thermal annealing process.

Step S2003, forming a first connecting metal and an inductive metal wire on the side, away from the substrate, of the epitaxial structure.

Specifically, the forming the first connecting metal and the inductive metal wire on the side, away from the substrate, of the epitaxial structure may further include: forming a first interlayer dielectric layer on the side, away from the substrate, of the epitaxial structure, a first through hole is formed in the first interlayer dielectric layer, and the first through hole exposes the first connecting metal layer. As shown in FIG. 27, a whole surface is covered with a layer of a material 140 of the first interlayer dielectric layer, the material of the first interlayer dielectric layer may be, for example, one or a combination of silicon oxide, aluminum oxide, silicon nitride, silicon oxynitride, or any other material that can be used as an insulating medium; next, as shown in FIG. 28, a first through hole 403 and a second through hole 404 are respectively formed by exposing, developing, etching, and the like, the first through hole 403 exposes the first connecting metal layer 13′, and the second through hole 404 exposes the second connecting metal layer 23.

The forming the first connecting metal on the side, away from the substrate, of the epitaxial structure includes: metallizing the first through hole to form the first connecting metal. The first connecting metal and the inductive metal wire may be formed at the same time, the inductive metal wire is in the second planar spiral shape, a first end of the first connecting metal is electrically connected with the first connecting metal layer, and a second end of the first connecting metal is electrically connected with a first end of the inductive metal wire; where the first end of the inductive metal wire is one end, corresponding to a center point of the second planar spiral shape, of the inductive metal wire; the first end of the two-dimensional electron gas is one end, corresponding to a center point of the first planar spiral shape, of the two-dimensional electron gas.

Specifically, as shown in FIG. 29, when metallizing the first through hole to form the first connecting metal 16′, the preparation method further includes: forming a first electrode metal 21 on a side, away from the substrate, of the first interlayer dielectric layer 14′, metallizing the second through hole to form a second connecting metal 24, and forming a second electrode metal 22 on the side, away from the substrate 11, of the first interlayer dielectric layer 14′. The first electrode metal 21 is electrically connected with a second end of the inductive metal wire 15′, a first end of the second connecting metal 24 is electrically connected with the second connecting metal layer 23, and a second end of the second connecting metal 24 is electrically connected with the second electrode metal 22; the first electrode metal 21 is used as a first electrode of the composite inductor, the second electrode metal 22 is used as a second electrode of the composite inductor, the current path of the composite inductor starts from the first electrode metal 21, to the second end of the inductive metal wire 15′, after passing through the inductive metal wire 15′in the second planar spiral shape, the current flows into the first connecting metal 16′ through the first end 151′ of the inductive metal wire 15′, subsequently, the current flows into the first end 1211 of the two-dimensional electron gas 121 through the first connecting metal layer 13′, after passing through the two-dimensional electron gas 121 in the first planar spiral shape, the current flows into the second connecting metal layer 23 through the second end of the two-dimensional electron gas 121, subsequently, the current flows into the second electrode metal 22 through the second connecting metal 24; of course, in some other embodiments, the current path may also be opposite, that is, the current flows in from the second electrode metal 22, and flows out from the first electrode metal 21.

Subsequently, a protective layer 28 may be further covered on the whole surface to form the structure shown in FIG. 18, and the protective layer 28 may be, for example, one or a combination of silicon oxide, aluminum oxide, silicon nitride, silicon oxynitride, or any other material that can be used as an insulating medium. The protective layer 28 can protect the composite inductor, prevent the composite inductor from being corroded by external water and oxygen, and prolong the service life of the composite inductor.

It should be noted that the above are only the preferred embodiments of the present disclosure and the technical principles used. Those skilled in the art will understand that the present disclosure is not limited to the specific embodiments described herein, and various obvious changes, readjustments and substitutions can be made by those skilled in the art without departing from the protection scope of the present disclosure. Therefore, although the present disclosure is described in more detail through the above embodiments, the present disclosure is not limited to the above embodiments, and may further include more other equivalent embodiments without departing from the concept of the present disclosure, and the scope of the present disclosure is determined by the scope of the appended claims.

What is claimed is:

1. A composite passive component, comprising:
a substrate;
an epitaxial structure, set on the substrate, wherein a two-dimensional electron gas with a specific pattern is formed in the epitaxial structure; and
a passive component body, set on a side, away from the substrate, of the epitaxial structure, and being in ohmic contact with the two-dimensional electron gas.

2. The composite passive component according to claim 1, wherein an isolation part is formed in the epitaxial structure, and the isolation part defines an area corresponding to the two-dimensional electron gas.

3. The composite passive component according to claim 1, wherein the specific pattern of the two-dimensional electron gas is adaptively set with the passive component body.

4. The composite passive component according to claim 1, wherein the composite passive component is a composite capacitor, the passive component body comprises: a metal capacitor structure, set on the side, away from the substrate, of the epitaxial structure, the metal capacitor structure comprises a first metal plate and a second metal plate, the second metal plate is located on a side, away from the substrate, of the first metal plate, and the first metal plate is insulated from the two-dimensional electron gas; and
along a thickness direction of the composite passive component, a total projection, on the substrate, of the first metal plate and the second metal plate at least partially overlaps with a projection, on the substrate, of the two-dimensional electron gas.

5. The composite passive component according to claim 4, wherein the two-dimensional electron gas is configured to be equipotential with the second metal plate; and
along the thickness direction of the composite passive component, a projection, on the substrate, of the first metal plate at least partially overlaps with the projection, on the substrate, of the two-dimensional electron gas.

6. The composite passive component according to claim 4, wherein the composite passive component further comprises:
a first interlayer dielectric layer, covering the epitaxial structure;
the metal capacitor structure is set on a side, away from the substrate, of the first interlayer dielectric layer, and the metal capacitor structure comprises the first metal plate, the second metal plate and a second interlayer dielectric layer.

7. The composite passive component according to claim 4, wherein along the thickness direction of the composite passive component, the projection, on the substrate, of the two-dimensional electron gas covers a projection, on the substrate, of the first metal plate and a projection, on the substrate, of the second metal plate.

8. The composite passive component according to claim 4, wherein the two-dimensional electron gas is insulated from the second metal plate.

9. The composite passive component according to claim 1, wherein the two-dimensional electron gas is in a first planar spiral shape, the composite passive component is a composite inductor, and the passive component body comprises:
a first connecting metal layer, being in ohmic contact with a first end of the two-dimensional electron gas;
an inductive metal wire, set on the side, away from the substrate, of the epitaxial structure, the inductive metal wire being in a second planar spiral shape;
a first connecting metal, wherein a first end of the first connecting metal is electrically connected with the first connecting metal layer, and a second end of the first connecting metal is electrically connected with a first end of the inductive metal wire,
wherein the first end of the inductive metal wire is one end, corresponding to a center point of the second planar spiral shape, of the inductive metal wire; the first end of the two-dimensional electron gas is one end, corresponding to a center point of the first planar spiral shape, of the two-dimensional electron gas.

10. The composite passive component according to claim 9, wherein a spiral direction of the first planar spiral shape is opposite to a spiral direction of the second planar spiral shape.

11. The composite passive component according to claim 9, wherein a width of the two-dimensional electron gas is greater than a width of the inductive metal wire.

12. The composite passive component according to claim 9, wherein the composite passive component further comprises a first interlayer dielectric layer, a first electrode metal, a second electrode metal, a second connecting metal layer and a second connecting metal;
the first interlayer dielectric layer is set on the side, away from the substrate, of the epitaxial structure; the inductive metal wire is set on a side, away from the substrate, of the first interlayer dielectric layer;
the first electrode metal, the second electrode metal and the inductive metal wire are set on a same layer, and the first electrode metal is electrically connected with a second end of the inductive metal wire;
the second connecting metal layer and the first connecting metal layer are set on a same layer, and the second connecting metal layer is in ohmic contact with a second end of the two-dimensional electron gas; and
the second connecting metal penetrates through the first interlayer dielectric layer, a first end of the second connecting metal is electrically connected with the second connecting metal layer, and a second end of the second connecting metal is electrically connected with the second electrode metal.

13. The composite passive component according to claim 9, wherein the composite passive component further comprises a second interlayer dielectric layer, a first ohmic metallized through hole and a second ohmic metallized through hole; the second interlayer dielectric layer is set between the first interlayer dielectric layer and the epitaxial structure; the first ohmic metallized through hole penetrates through the second interlayer dielectric layer, and the second ohmic metallized through hole penetrates through the second interlayer dielectric layer; and
the first connecting metal layer is in ohmic contact with the first end of the two-dimensional electron gas through the first ohmic metallized through hole, and the second connecting metal layer is in ohmic contact with the second end of the two-dimensional electron gas through the second ohmic metallized through hole.

14. The composite passive component according to claim 9, further comprising:
a protective layer covering the inductive metal wire.

15. A preparation method for a composite passive component, comprising:
providing a substrate;
forming an epitaxial structure layer on the substrate by epitaxy;
performing ion implantation on the epitaxial structure layer to form an isolation part, to define an area corresponding to a two-dimensional electron gas; and
setting a passive component body on a side, away from the substrate, of the epitaxial structure, and making the passive component body be in ohmic contact with the two-dimensional electron gas.

16. The preparation method according to claim 15, wherein the passive component body comprises a metal capacitor structure, and the setting a passive component body on a side, away from the substrate, of the epitaxial structure, comprises:
forming the metal capacitor structure on the side, away from the substrate, of the epitaxial structure, the metal capacitor structure comprises a first metal plate and a second metal plate, the second metal plate is located on a side, away from the substrate, of the first metal plate, and the first metal plate is insulated from the two-dimensional electron gas; and
along a thickness direction of the composite passive component, a total projection, on the substrate, of the first metal plate and the second metal plate at least partially overlaps with a projection, on the substrate, of the two-dimensional electron gas.

17. The preparation method according to claim 16, wherein the forming the metal capacitor structure on the side, away from the substrate, of the epitaxial structure, comprises:
forming the first metal plate, so that along the thickness direction of the composite passive component, a projection, on the substrate, of the first metal plate at least partially overlaps with a projection, on the substrate, of the two-dimensional electron gas;
wherein when forming the metal capacitor structure on the side, away from the substrate, of the epitaxial structure, the preparation method further comprises:
forming a connecting structure, wherein the connecting structure is in ohmic contact with the two-dimensional electron gas and is electrically connected with the second metal plate.

18. The preparation method according to claim 15, wherein the epitaxial structure comprises a two-dimensional electron gas in a first planar spiral shape, the passive component body comprises a first connecting metal layer, an inductive metal wire and a first connecting metal;
the setting a passive component body on a side, away from the substrate, of the epitaxial structure, comprises:
forming the first connecting metal layer on the side, away from the substrate, of the epitaxial structure, the first connecting metal layer being in ohmic contact with a first end of the two-dimensional electron gas; and
forming the first connecting metal and the inductive metal wire on the side, away from the substrate, of the epitaxial structure;
wherein the inductive metal wire is in a second planar spiral shape, a first end of the first connecting metal is electrically connected with the first connecting metal layer, a second end of the first connecting metal is electrically connected with a first end of the inductive metal wire; the first end of the inductive metal wire is one end, corresponding to a center point of the second planar spiral shape, of the inductive metal wire; the first end of the two-dimensional electron gas is one end, corresponding to a center point of the first planar spiral shape, of the two-dimensional electron gas.

19. The preparation method according to claim 18, wherein before the forming the first connecting metal and the inductive metal wire on the side, away from the substrate, of the epitaxial structure, the preparation method further comprises:
forming a first interlayer dielectric layer on the side, away from the substrate, of the epitaxial structure, a first through hole being formed in the first interlayer dielectric layer, and the first through hole exposing the first connecting metal layer;
wherein the forming the first connecting metal on the side, away from the substrate, of the epitaxial structure comprises:
metallizing the first through hole to form the first connecting metal.

20. The preparation method according to claim 19, wherein before the forming the first connecting metal layer on the side, away from the substrate, of the epitaxial structure, the preparation method further comprises:
forming a second interlayer dielectric layer on the side, away from the substrate, of the epitaxial structure, a first ohmic through hole and a second ohmic through hole being formed in the second interlayer dielectric layer, the first ohmic through hole exposing a first end of the two-dimensional electron gas, and the second ohmic through hole exposing a second end of the two-dimensional electron gas;
wherein when forming the first connecting metal layer on the side, away from the substrate, of the epitaxial structure, the preparation method further comprises:
metallizing the first ohmic through hole to form a first ohmic metallized through hole, forming a second connecting metal layer on the side, away from the substrate, of the epitaxial structure, and metallizing the second ohmic through hole to form a second ohmic metallized through hole; the first connecting metal layer being in ohmic contact with the first end of the two-dimensional electron gas through the first ohmic metallized through hole, the second connecting metal layer being in ohmic contact with the second end of the two-dimensional electron gas through the second ohmic metallized through hole;
wherein when forming a first interlayer dielectric layer on the side, away from the substrate, of the epitaxial structure, the preparation method further comprises:
forming the first interlayer dielectric layer with a second through hole, the second through hole exposing the second connecting metal layer;
wherein when metallizing the first through hole to form the first connecting metal, and forming the inductive metal wire on the side, away from the substrate, of the first interlayer dielectric layer, the preparation method further comprises:
forming a first electrode metal on the side, away from the substrate, of the first interlayer dielectric layer, metallizing the second through hole to form a second connecting metal, and forming a second electrode metal on the side, away from the substrate, of the first interlayer dielectric layer; wherein the first electrode metal is electrically connected with a second end of the inductive metal wire; a first end of the second connecting metal is electrically connected with the second connecting metal layer, and a second end of the second connecting metal is electrically connected with the second electrode metal.
